(19) United States
(12) Patent Application Publication
(10) Pub. No.: US 2025/0190654 A1
(43) Pub. Date: Jun. 12, 2025

(54) FINITE ELEMENT MODEL CONSTRUCTION METHOD AND TERMINAL FOR DISSOLUTION PROCESS OF POROUS MEDIUM REEF LIMESTONE

(71) Applicants: SANYA SCIENCE AND EDUCATION INNOVATION PARK OF WUHAN UNIVERSITY OF TECHNOLOGY, Sanya City (CN); WUHAN UNIVERSITY OF TECHNOLOGY, Wuhan City (CN)

(72) Inventors: Dongsheng XU, Wuhan City (CN); Shanshan ZHANG, Wuhan City (CN); Yue QIN, Sanya City (CN)

(73) Assignees: SANYA SCIENCE AND EDUCATION INNOVATION PARK OF WUHAN UNIVERSITY OF TECHNOLOGY, Sanya City (CN); WUHAN UNIVERSITY OF TECHNOLOGY, Wuhan City (CN)

(21) Appl. No.: 18/741,844

(22) Filed: Jun. 13, 2024

(30) Foreign Application Priority Data
Dec. 11, 2023 (CN) 2023116874156

(51) Int. Cl. G06F 30/23; G06T 17/20

(52) U.S. Cl. CPC G06F 30/23; G06T 17/20

(57) ABSTRACT

A finite element model construction method and terminal for the dissolution process of porous medium reef limestone involves scanning a cut reef limestone test block. The scan results are visually analyzed to obtain a two-dimensional topographic diagram of the test block. A position map of the limestone in a carbonic acid solution is drawn on the diagram, and an image position function is derived through finite element image processing. Initial positions of the solid and liquid phases are determined in a level set initial solution based on this function. During the dissolution process, a boundary movement speed related to the dissolution rate is set at the reaction interface of the level set solution and the reef limestone, and boundary information of the solid and liquid phases is transferred. A chemical reaction and mass transfer model is then constructed based on this transfer process.

### TECHNICAL FIELD

The present invention relates to the technical field of rock dissolution test method, and specifically relates to a finite element model construction method and terminal for dissolution process of porous medium reef limestone.

### BACKGROUND ART

With the vigorous development of reef construction, the stability of reef limestone, as the main engineering construction material, has a serious impact on the reliability of island reef engineering. Since the main component of reef limestone is calcium carbonate, the increase of carbon dioxide content in the atmosphere leads to the increase of carbon dioxide partial pressure in the ocean, which leads to ocean acidification and directly affects the pH value of seawater. The acidification of seawater will erode the reef limestone. In order to deeply understand the performance characteristics of reef limestone, it is necessary to study its dissolution characteristics first.

Previous studies often focus on macroscopic mechanical tests and field experiments, the dissolution aspect is mainly about finding out the relationship between the dissolution amount of carbonate rocks and temperature and pressure and obtaining the quantitative relationship between various surface reaction sites and the space-time rate variance observed in the experiment. There are few studies on the dissolution process of reef limestone, and the characteristics of developed pores and cracks and complex pore structures in reef limestone are neglected.

At present, the commonly used grid moving method has a problem in the simulation of dissolution, the particles gradually become smaller with the dissolution progresses, which makes it more and more difficult to generate the grid for simulation. The reduction of particles makes the mesh prone to distortion, which leads to a decrease in the convergence of the simulation. Considering the porous medium properties of the reef limestone, the shape and size of the internal pores are different, and a large number of branches are broken or disappeared during the dissolution process. In addition, due to the rich pore structure of reef limestone, a large number of grids are needed to accurately describe the dissolution process, which increases the computational cost.

### SUMMARY

The present invention proposes a finite element model construction method for dissolution process of porous medium reef limestone to solve the technical problems of existing numerical simulation and difficult convergence.

In order to solve the above technical problems, the present invention provides a finite element model construction method for dissolution process of porous medium reef limestone, comprising the following steps:
step S1: carrying out a whole scanning of a reef limestone test block that has been cut;
step S2: performing a visual analysis on a scanning result to obtain a two-dimensional section topographic diagram of the reef limestone test block;
step S3: drawing a position map of the reef limestone in a carbonic acid solution on the two-dimensional section topographic map, and obtaining an image position function through a finite element image processing;
step S4: determining initial positions of a solid phase and a liquid phase in a level set initial solution based on the image position function;
step S5: in a dissolution process, setting a boundary movement speed related to a dissolution rate at the reaction interface of level set solution and reef limestone, and transferring boundary information of solid phase and liquid phase;
step S6: constructing a chemical reaction and mass transfer model based on the transfer process in step S5.

Preferably, the method of overall scanning in step S1 comprises the following steps: scanning the whole of the reef limestone test block that has been cut by using a high-precision CT to obtain its internal pore structure distribution.

Preferably, step S2 comprises the following steps: using imaging data analysis software, visually analyzing and cutting the whole reef limestone scanned by CT, and then obtaining the two-dimensional section topography map of the test block by a grayscale processing and a binarization processing.

Preferably, the image position function described in step S3 is denoted by an interpolation function as follows:

$$im ( x , y ) = \{ \begin{matrix}0 , solid phase \\ 1 , fluid phase\end{matrix} ;$$

where, (x, y) denotes a set of coordinate points of the phase position.

Preferably, step S4 comprises the following steps: using the image position function in a two-phase flow level set function to specify the initial positions of the solid phase and the liquid phase in a computational domain, respectively, the expression is:

$$\frac{\partial φ}{\partial t} + u \cdot ∇ φ = γ ∇ \cdot ( ε ∇ φ - φ ( 1 - φ ) \frac{∇ φ}{\vert ∇ φ \vert} ; \\ φ = im ( x , y ) ;$$

where φ is a level set phase variable, if φ denotes the fluid phase, then (1−φ) denotes the solid phase, u denotes a velocity field, γ denotes a reinitialization parameter, ε denotes an interface thickness control parameter, and t denotes a time.

Preferably, the expression of step S5 is:

$$u = {MR}_{{CaCO}_{3}} ; \\ {R}_{{CaCO}_{3}} = ( {k}_{1} {a}_{{H}^{{}_{+}}} + {k}_{2} {a}_{{CO}_{2} ( aq )} + {k}_{3} {a}_{{H}_{2} O} ) ( 1 - {10}^{0.67 log 10 ( ω )} ) ;$$

where M denotes a molar volume of reef limestone, R_{CaCO}_{₃} denotes a dissolution reaction rate of reef limestone; k₁, k₂ and k₃ denote reaction constants of reef limestone with [H⁺], CO₂ (aq) and H₂O in the solution, a_{H}_{⁺}, a_{CO}_{₂} (aq) and a_{H}_{₂}_{O} denote an activity of a substance, that is, aᵢ=cᵢγ, γ denotes an activity coefficient of the substance, cᵢ denotes a concentration of the substance, ω denotes a saturation of a solution.

Preferably, in step S6, the expression of the chemical reaction and mass transfer model is:

$$\frac{\partial {c}_{i}}{\partial t} + ∇ \cdot ( - {D}_{i} {∇}_{{c}_{i}} ) = {R}_{i} ;$$

where cᵢ denotes the concentration, Dᵢ is a diffusion coefficient, ∇cᵢ is a concentration gradient, and Rᵢ is a reaction rate of the substance.

The present invention also provides a terminal, comprising a memory and a processor;

the memory, which is used to store a computer program and a finite element model construction method for dissolution process of porous medium reef limestone;

the processor, which is used to perform the computer program and the finite element model construction method for dissolution process of porous medium reef limestone to realize the above method.

The present invention also provides a computer-readable storage medium for storing computer instructions, the computer instructions are used to realize the above method when the processor is executed.

The beneficial effects of the present invention comprise at least: the level set method is a numerical technique for interface tracking and shape modeling, which can easily track the topological structure change of the object. In addition, image processing technology generates computational domain image functions, which can greatly reduce the geometric meshing of the model and improve computational efficiency. Combining the advantages of the two, the dissolution process of the porous medium structure of the real reef limestone can be studied, which is helpful in understanding the dissolution mechanism of the reef limestone and reducing the risk of ground collapse or dissolution collapse of the island reef project caused by dissolution.

Any complex shape reef limestone structure can be imported through image processing, which avoids the difficulty of meshing caused by the existence of small cells when the geometric structure is directly imported into the model, reduces the number of meshing and increases the calculation cost. Meanwhile, the use of the level set interface tracking method can avoid the problem of grid distortion that cannot be handled well when using the dynamic grid method, that is, the convergence problem caused by the large grid deformation of the porous medium reef limestone due to the dissolution of the original solid position supplemented by the liquid. It can be used to study the changing trend of ion concentration in solution after dissolution and the development process of pore dissolution in reef limestone.

### BRIEF DESCRIPTION OF THE DRAWINGS

FIG. 1 is a process flow diagram of an embodiment of the present invention.

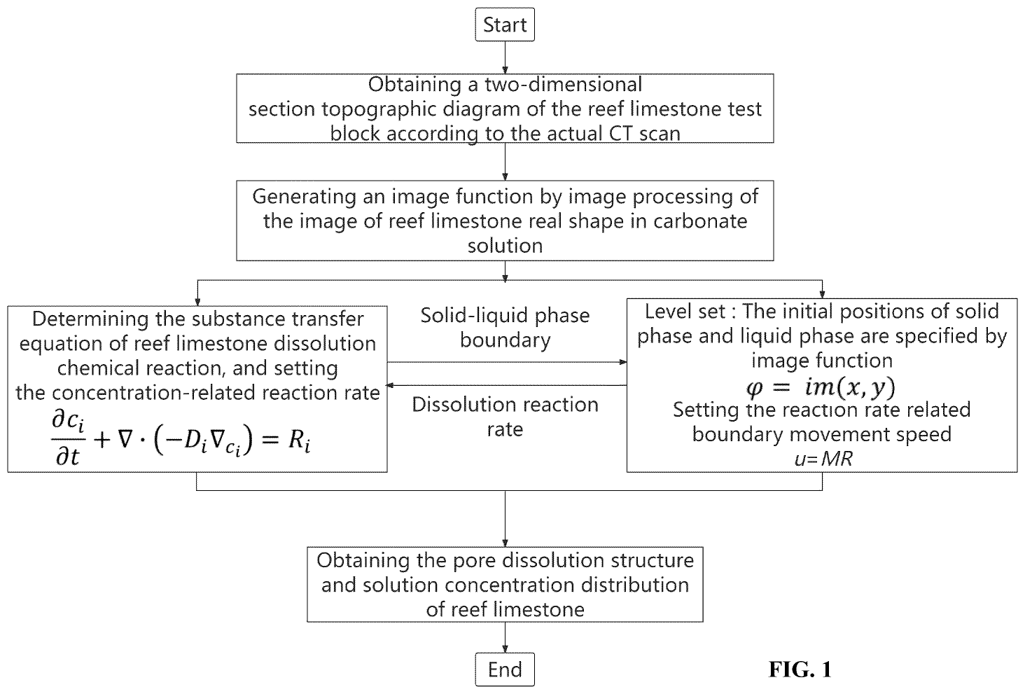

### DETAILED DESCRIPTION OF THE EMBODIMENTS

The following clearly and completely describes the technical solutions in embodiments the present invention in combination with the drawings of the embodiments of the present disclosure. Apparently, the described embodiments are only some but not all of the embodiments of the present disclosure. All other embodiments obtained by those of ordinary skill in the art based on the embodiments of the present disclosure without involving any creative effort shall fall within the scope of protection of the present disclosure.

The embodiment of the present invention provides a finite element model construction method for dissolution process of porous medium reef limestone, comprising the following steps:

step S1: a whole scanning of a reef limestone test block that has been cut is carried out.

Specifically, the overall scanning of the cut reef limestone test block is mainly using a high-precision CT scanning to obtain its internal pore structure distribution.

Step S2: a visual analysis on a scanning result is performed to obtain a two-dimensional section topographic diagram of the reef limestone test block.

Specifically, the whole reef limestone scanned by CT is visually analyzed and cut, and then the two-dimensional section topography map of the test block is obtained by a grayscale processing and a binarization processing, exemplarily, Avizo imaging data analysis software is used for visual analysis.

Step S3: a position map of the reef limestone in a carbonic acid solution is drawn on the two-dimensional section topographic map, and an image position function is obtained through a finite element image processing.

Specifically, on the basis of step S2, the position map of reef limestone in solution is drawn and imported into the finite element software, and the image position function of solid phase and fluid phase is generated by image processing technology, and the image position is expressed by micro interpolation function as follows:

$$im ( x , y ) = \{ \begin{matrix}0 , solid phase \\ 1 , fluid phase\end{matrix} ;$$

where, (x, y) denotes a set of coordinate points of the phase position.

Step S4: initial positions of a solid phase and a liquid phase in a level set initial solution are determined based on the image position function.

Specifically, the image position function generated by step S3 is used in a two-phase flow level set function to specify the initial positions of the solid phase and the liquid phase in a computational domain, respectively, the expression is:

$$\frac{\partial φ}{\partial t} + u \cdot ∇ φ = γ ∇ \cdot ( ε ∇ φ - φ ( 1 - φ ) \frac{∇ φ}{\vert ∇ φ \vert} ; \\ φ = im ( x , y ) ;$$

where φ is a level set phase variable, if φ denotes the fluid phase, then (1−φ) denotes the solid phase, u denotes a velocity field, γ denotes a reinitialization parameter, ε denotes an interface thickness control parameter, and t denotes a time.

Step S5: in a dissolution process, a boundary movement speed related to a dissolution rate is set at the reaction interface of level set solution and reef limestone, and boundary information of solid phase and liquid phase is transferred.

Specifically, in the process of reef limestone being dissolved by solution, the dissolution boundary of solid phase reef limestone is supplemented by solution, which leads to the change of solid-liquid phase interface, and the information will be fed back to the whole chemical reaction process, the moving speed is that the velocity field u in step S4 is related to the dissolution rate of reef limestone, and the expression is:

$$u = {MR}_{{CaCO}_{3}} ; \\ {R}_{{CaCO}_{3}} = ( {k}_{1} {a}_{{H}^{{}_{+}}} + {k}_{2} {a}_{{CO}_{2} ( aq )} + {k}_{3} {a}_{{H}_{2} O} ) ( 1 - {10}^{0.67 log 10 ( ω )} ) ;$$

where M denotes a molar volume of reef limestone, R_{CaCO}_{₃} denotes a dissolution reaction rate of reef limestone; k₁, k₂ and k₃ denote reaction constants of reef limestone with [H⁺], CO₂ (aq) and H₂O in the solution, a_{H}_{⁺}, a_{CO}_{₂} (aq) and a_{H}_{₂}_{O} denote an activity of a substance, that is, aᵢ=cᵢγ, γ denotes an activity coefficient of the substance, cᵢ denotes a concentration of the substance, ω denotes a saturation of a solution.

Step S6: a chemical reaction and mass transfer model are constructed based on the transfer process in step S5.

Specifically, the chemical reaction rate R_{CaCO}_{₃} of reef limestone is affected by the concentration of the substance in the solution, the concentration of the substance in the solution will transfer from high concentration to low concentration to produce diffusion with the occurrence of the dissolution reaction. When the substance concentration changes, the reaction rate R_{CaCO}_{₃} also changes, thus affecting the speed of the whole reef limestone dissolution reaction. Meanwhile, due to the change of reef limestone dissolution reaction rate, the speed of solid-liquid boundary movement in level set also changes. The following formula can be used to calculate the concentration and reaction rate of different substances in the solution with time:

$$\frac{\partial {c}_{i}}{\partial t} + ∇ \cdot ( - {D}_{i} {∇}_{{c}_{i}} ) = {R}_{i} ;$$

where cᵢ denotes the concentration, Dᵢ is a diffusion coefficient, ∇cᵢ is a concentration gradient, and Rᵢ is a reaction rate of the substance.

The present invention also provides a terminal, comprising a memory and a processor;

the memory, which is used to store a computer program and a finite element model construction method for dissolution process of porous medium reef limestone;

the processor, which is used to perform the computer program and the finite element model construction method for dissolution process of porous medium reef limestone to realize the above method.

The present invention also provides a computer-readable storage medium for storing computer instructions, the computer instructions are used to realize the above method when the processor is executed.

The technical features of the above embodiments can be arbitrarily combined. In order to make the description concise, all possible combinations of the technical features in the above embodiments are not described, and only the preferred embodiments of the present invention are expressed. The description is more specific and detailed, but it cannot be understood as a limitation on the scope of the present invention patent. As long as there is no contradiction in the combination of these technical features, it should be considered as the scope of this specification.

It should be noted that several variations and modifications can be made by one skilled in the art without departing from the inventive concept, which is within the scope of the present invention. Therefore, the scope of protection of the invention patent should be subject to the attached claims.

What is claimed is:

1. A finite element model construction method for dissolution process of porous medium reef limestone, comprising the following steps:
step S1: carrying out a whole scanning of a reef limestone test block that has been cut;
step S2: performing a visual analysis on a scanning result to obtain a two-dimensional section topographic diagram of the reef limestone test block;
step S3: drawing a position map of the reef limestone in a carbonic acid solution on the two-dimensional section topographic map, and obtaining an image position function through a finite element image processing;
step S4: determining initial positions of a solid phase and a liquid phase in a level set initial solution based on the image position function;
step S5: in a dissolution process, setting a boundary movement speed related to a dissolution rate at the reaction interface of level set solution and reef limestone, and transferring boundary information of solid phase and liquid phase;
step S6: constructing a chemical reaction and mass transfer model based on the transfer process in step S5.

2. The finite element model construction method for dissolution process of porous medium reef limestone according to claim 1, wherein the method of overall scanning in step S1 comprises the following steps: scanning the whole of the reef limestone test block that has been cut by using a high-precision CT to obtain its internal pore structure distribution.

3. The finite element model construction method for dissolution process of porous medium reef limestone according to claim 2, wherein step S2 comprises the following steps: using imaging data analysis software, visually analyzing and cutting the whole reef limestone scanned by CT, and then obtaining the two-dimensional section topography map of the test block by a grayscale processing and a binarization processing.

4. The finite element model construction method for dissolution process of porous medium reef limestone according to claim 1, wherein the image position function described in step S3 is denoted by an interpolation function as follow:
$$im ( x , y ) = \{ \begin{matrix}0 , solid phase \\ 1 , fluid phase\end{matrix} ;$$
where, (x, y) denotes a set of coordinate points of the phase position.

5. The finite element model construction method for dissolution process of porous medium reef limestone according to claim 4, wherein step S4 comprises the following steps: using the image position function in a two-phase flow level set function to specify the initial positions of the solid phase and the liquid phase in a computational domain, respectively, the expression is:
$$\frac{\partial φ}{\partial t} + u \cdot ∇ φ = γ ∇ \cdot ( ε ∇ φ - φ ( 1 - φ ) \frac{∇ φ}{\vert ∇ φ \vert} ; \\ φ = im ( x , y ) ;$$
where φ is a level set phase variable, if φ denotes the fluid phase, then (1−φ) denotes the solid phase, u denotes a velocity field, γ denotes a reinitialization parameter, ε denotes an interface thickness control parameter, and t denotes a time.

6. The finite element model construction method for dissolution process of porous medium reef limestone according to claim 5, wherein the expression of step S5 is:
$$u = {MR}_{{CaCO}_{3}} ; \\ {R}_{{CaCO}_{3}} = ( {k}_{1} {a}_{{H}^{{}_{+}}} + {k}_{2} {a}_{{CO}_{2} ( aq )} + {k}_{3} {a}_{{H}_{2} O} ) ( 1 - {10}^{0.67 log 10 ( ω )} ) ;$$
where M denotes a molar volume of reef limestone, R_{CaCo}_{₃} denotes a dissolution reaction rate of reef limestone; k₁, k₂ and k₃ denote reaction constants of reef limestone with [H⁺], CO₂ (aq) and H₂O in the solution, a_{H}_{⁺}, a_{CO}_{₂} (aq) and a_{H}_{₂}_{O} denote an activity of a substance, that is, aᵢ=cᵢγ, γ denotes an activity coefficient of the substance, cᵢ denotes a concentration of the substance, ω denotes a saturation of a solution.

7. The finite element model construction method for dissolution process of porous medium reef limestone according to claim 6, wherein in step S6, the expression of the chemical reaction and mass transfer model is:
$$\frac{\partial {c}_{i}}{\partial t} + ∇ \cdot ( - {D}_{i} {∇}_{{c}_{i}} ) = {R}_{i} ;$$
where cᵢ denotes the concentration, Dᵢ is a diffusion coefficient, ∇cᵢ is a concentration gradient, and Rᵢ is a reaction rate of the substance.

8. A terminal, comprising a memory and a processor;
the memory, which is used to store a computer program and a finite element model construction method for dissolution process of porous medium reef limestone;
the processor, which is used to perform the computer program and the finite element model construction method for dissolution process of porous medium reef limestone to realize the method according to claim 1.

9. A computer-readable storage medium for storing computer instructions, the computer instructions are used to realize the method according to claim 1 when the processor is executed.
